(19) United States
(12) Patent Application Publication
(10) Pub. No.: US 2023/0326897 A1
(43) Pub. Date: Oct. 12, 2023

(54) DIE BACKSIDE METALLIZATION METHODS AND APPARATUS

(71) Applicant: Wolfspeed, Inc., Durham, NC (US)

(72) Inventors: Daniel Richter, Raleigh, NC (US); Frank Stepniak, Apex, NC (US)

(21) Appl. No.: 17/658,691

(22) Filed: Apr. 11, 2022

(51) Int. Cl. H01L 23/00

(52) U.S. Cl. CPC H01L 24/29; H01L 24/27; H01L 24/83; H01L 2224/29082; H01L 2224/29144; H01L 2224/29139; H01L 2224/29147; H01L 2224/29109; H01L 2224/29113; H01L 2224/29111; H01L 2224/29116; H01L 2224/2745; H01L 2224/27452; H01L 2224/27464; H01L 2224/83203; H01L 2224/83825; H01L 2224/8383; H01L 2924/35121

(57) ABSTRACT

Die backside metallization methods and apparatus are disclosed. In one aspect, a method of forming a die involves providing a backside metallization layer on the die prior to attaching the die to a chip carrier. Various possible attaching techniques such as a backside solder, transient liquid phase bonding, or solid state diffusion bonding may be used. The resulting apparatus may have a relatively thin bond layer that has a relatively uniform thickness. The thin bond layer having an essentially constant thickness provides good thermal properties while being resistant to delamination from thermal cycling.

### BACKGROUND

### I. Field of the Disclosure

The technology of the disclosure relates generally to die formation and methods for attaching dies to chip carriers such as lead frames or power electronic substrates such as direct bonded copper substrates.

### II. Background

Computing devices abound in modern society, and more particularly, mobile communication devices have become increasingly common. The prevalence of these mobile communication devices is driven in part by the many functions that are now enabled on such devices. Increased processing capabilities in such devices means that mobile communication devices have evolved from pure communication tools into sophisticated mobile entertainment centers, thus enabling enhanced user experiences. With the advent of the myriad functions available to such devices, there has been a steady increase in the size of integrated circuits (ICs) needed to provide the processing power to enable the functions. This increase is present even though individual transistor size within the IC may be decreasing. Attaching the die containing such ICs to a chip carrier such as a lead frame in traditional fashions is inefficient and leaves room for innovation.

### SUMMARY

Aspects disclosed in the detailed description include die backside metallization methods and apparatus. In a particular aspect, a method of forming a die involves providing a backside metallization layer on the die prior to attaching the die to a chip carrier. Various possible attaching techniques such as a backside solder, transient liquid phase bonding, or solid state diffusion bonding may be used. The resulting apparatus may have a relatively thin bond layer that has a relatively uniform thickness. The thin bond layer having an essentially constant thickness provides good thermal properties while being resistant to delamination from thermal cycling.

In this regard in one aspect, a method for forming a semiconductor device is disclosed. The method comprises forming a metallization layer on an exterior surface of a die. The method also comprises attaching the die to a chip carrier using the metallization layer.

In another aspect, a semiconductor device is disclosed. The semiconductor device comprises a chip carrier. The semiconductor device also comprises a die. The semiconductor device also comprises a gold-free bond layer attaching the die to the chip carrier. The gold-free bond layer has a relatively uniform thickness of approximately 20 microns (μm) or less but more than 0.01 μm.

### BRIEF DESCRIPTION OF THE DRAWINGS

FIG. 1 is a side elevation cross-sectional view of a semiconductor device formed according to exemplary aspects of the present disclosure;

FIG. 2 is a flowchart illustrating an exemplary process for making a semiconductor device according to the present disclosure;

FIGS. 3A-3D illustrate steps within the flowchart of FIG. 2; and

FIG. 4 is a side elevation cross-sectional view of an alternate semiconductor device formed according to exemplary aspects of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Aspects disclosed in the detailed description include die backside metallization methods and apparatus. In a particular aspect, a method of forming a die involves providing a backside metallization layer on the die prior to attaching the die to a chip carrier. Various possible attaching techniques such as a backside solder, transient liquid phase bonding, or solid state diffusion bonding may be used. The resulting apparatus may have a relatively thin bond layer that has a relatively uniform thickness. The thin bond layer having an essentially constant thickness provides good thermal properties while being resistant to delamination from thermal cycling.

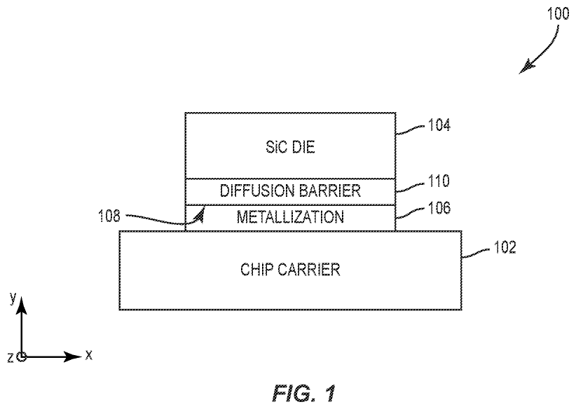

In this regard, FIG. 1 illustrates a semiconductor device 100 formed according to exemplary processes of the present disclosure. The semiconductor device 100 may include a chip carrier 102, such as a lead frame or power electronic substrates such as direct bonded copper substrates. A die 104, such as a silicon carbide die, may be attached to the chip carrier 102 according to exemplary aspects of the present disclosure. Specifically, a thin metallization layer 106 is applied to an exterior surface, and more particularly to a backside 108 of the die 104 before attaching the die 104 to the chip carrier 102. The backside 108 of the die 104 may be formed by a diffusion barrier 110 to which the metallization layer 106 is secured.

In an exemplary aspect, the metallization layer 106 forms a relatively thin bond layer having a relatively uniform thickness of approximately 20 microns (μm) or less but more than 0.01 μm. In a further exemplary aspect, the metallization layer 106 forms a thin bond layer having a relatively uniform thickness of approximately 10 μm or less but more than 0.01 μm. In a further exemplary aspect, the metallization layer 106 forms a thin bond layer having a relatively uniform thickness of approximately 5 μm or less but more than 0.01 μm. It is specifically contemplated that the bond layer is a gold-free bond layer and may use materials such as silver (Ag), copper (Cu), indium (In), bismuth (Bi), lead tin (PbSn), or tin silver (SnAg). While a gold-free bond layer is specifically contemplated, the present disclosure is not so limited and the process 200 outlined below may use a gold-based metallization layer if needed or desired.

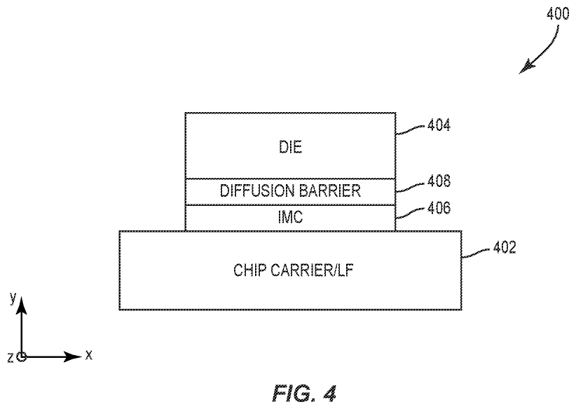

As illustrated, the semiconductor device 100 has some free solder (e.g., metallization layer 106) remaining after the die 104 is attached to the chip carrier 102. This free solder may act as an added stress buffer to prevent die cracking or voiding (e.g., which may lead to delamination). Alternatively, as illustrated in FIG. 4, the solder may at least partially merge with the diffusion barrier and also merges with the chip carrier to form an intermetallic compound (IMC) layer.

As used herein the term “relatively” means within a five percent tolerance, and the term “approximately” means within five percent.

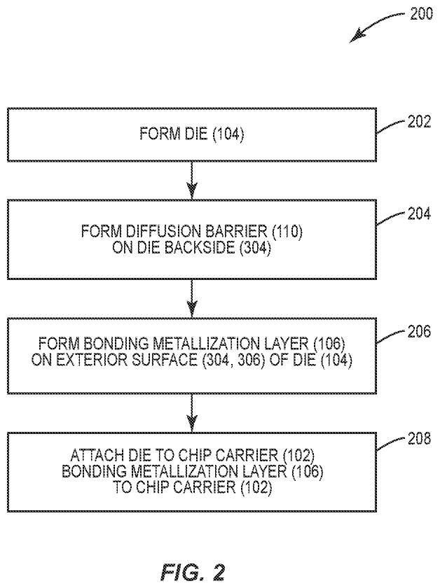

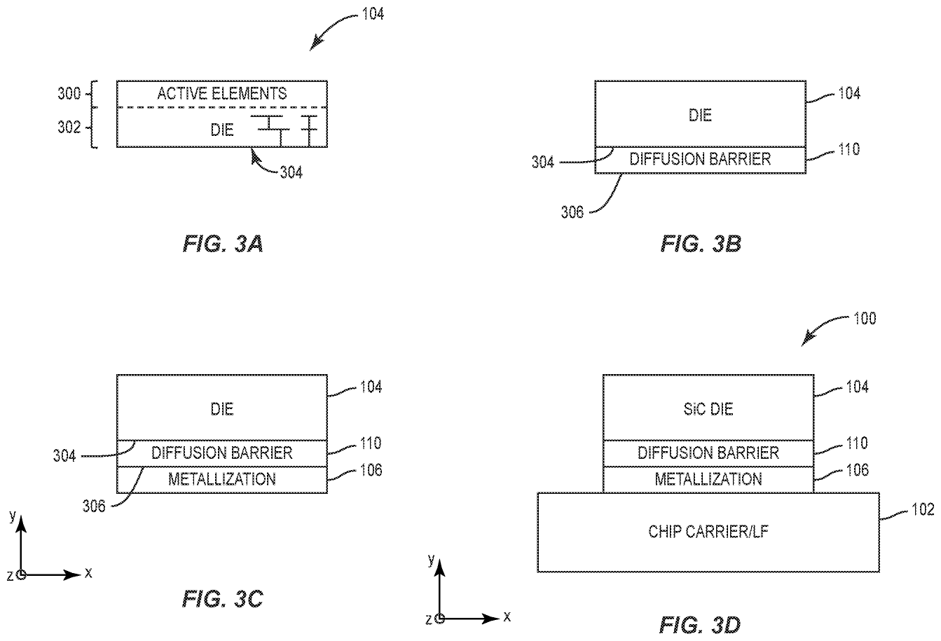

FIG. 2 illustrates a process 200 for forming the semiconductor device 100 with intermediate stages illustrated in FIGS. 3A-3D. In particular, the process 200 starts by forming a die 104. In an exemplary aspect, the die 104 may be formed from an active layer 300 (block 202, see FIG. 3A) where active elements such as transistors are formed and combined into elements such as memory cells, inverters, amplifiers, or the like and a substrate 302, which may include internal metallization layers and vias that interconnect the active elements within the active layer 300. The die 104 may include a first backside on a first exterior surface 304 positioned oppositely from the active layer 300. The die 104 may be part of a larger wafer that includes other dies (not shown).

The process 200 continues by optionally forming the diffusion barrier 110 within the die 104 or on the exterior surface 304 thereby forming a new exterior surface 306 (block 204, see FIG. 3B).

The process 200 continues by forming a bonding metallization layer 106 on an exterior surface of the die 104. The exterior surface may be the surface 304 or the surface 306 depending on whether there is a diffusion barrier 110 (block 206, see FIG. 3C). In an exemplary aspect, the metallization layer 106 is formed having a thickness (i.e., in the y-direction) less than approximately 20 μm, but more than 0.01 μm. In a further exemplary aspect, the metallization layer 106 is formed having a thickness (i.e., in the y-direction) less than approximately 5 μm but more than 0.01 μm. As noted above, the metallization layer 106 may be formed from gold (Au), silver (Ag), copper (Cu), indium (In), bismuth (Bi), tin (Sn), lead tin (PbSn), or tin silver (SnAg). Alternatively, the metallization layer 106 may be formed from gold tin (AuSn).

Where multiple dies are formed on a single wafer, applying the metallization layer 106 in this fashion allows the metallization layer 106 to be applied in a parallel fashion and then the wafer may be singulated. Traditional techniques are applied to metallization layers serially after singulation, which can result in wasted solder material as well as increasing process steps.

In an exemplary aspect, the metallization layer 106 may be formed by electroplating. In another exemplary aspect, the metallization layer 106 may be formed by electroless plating. In another exemplary aspect, the metallization layer 106 may be formed by chemical vapor deposition (CVD). In another exemplary aspect, the metallization layer 106 may be formed by physical vapor deposition (PVD).

The process 200 continues by attaching the die 104 to the chip carrier 102 by bonding the metallization layer 106 to the chip carrier 102 (block 208, see FIG. 3D). In an exemplary aspect, block 208 may be done by diffusion bonding (also sometimes referred to as solid state diffusion bonding) the die 104 to the chip carrier 102. Such diffusion bonding may take place at less than approximately 250° C. In another exemplary aspect, block 208 may be done by thermocompression bonding the die 104 to the chip carrier 102. Further, atmospheric pressure may be reduced during the attaching to facilitate removal of voids. Such reduction may be done using a vacuum reflow oven to melt the metallization layer 106 and bond to the chip carrier 102. Alternatively, an actively reducing metal oxide environment may be used, which employs a reducing agent at normal or reduced atmospheric pressure (e.g., a forming gas).

Most of these bonding techniques leave free solder between the die 104 and the chip carrier 102. The presence of such free solder acts as a sort of shock absorber or stress buffer and may assist in prevention of die cracking, voiding, or delamination. Alternatively, block 208 may be done by transient liquid phase bonding (TLPB) the die 104 to the chip carrier 102. TLPB is likely to consume all the metallization layer 106 and form an IMC layer as better illustrated by semiconductor device 400 of FIG. 4.

In this regard, FIG. 4 illustrates the semiconductor device 400 with a chip carrier 402 attached to a die 404 by an IMC layer 406 that is formed when the solder material merges with a diffusion barrier material (from a diffusion barrier 408) and/or the chip carrier 402 such that there is no remaining discernable solder material layer.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

What is claimed is:

1. A method for forming a semiconductor device, comprising:
forming a metallization layer on an exterior surface of a die; and
attaching the die to a chip carrier using the metallization layer.

2. The method of claim 1, wherein forming the metallization layer comprises forming a metallization layer having a thickness less than approximately 20 microns (μm), but more than 0.01 μm.

3. The method of claim 1, wherein forming the metallization layer comprises forming a metallization layer having a thickness less than approximately 5 microns (μm) but more than 0.01 μm.

4. The method of claim 1, wherein forming the metallization layer comprises forming a diffusion barrier in the metallization layer.

5. The method of claim 1, wherein forming the metallization layer comprises forming a metallization layer from one of gold (Au), silver (Ag), copper (Cu), indium (In), bismuth (Bi), tin (Sn), lead tin (PbSn), or tin silver (SnAg).

6. The method of claim 1, wherein forming the metallization layer comprises forming a metallization layer from gold tin (AuSn).

7. The method of claim 1, wherein forming the metallization layer on the exterior surface of the die comprises forming the metallization layer on a wafer and subsequently singulating the wafer into at least the die.

8. The method of claim 1, wherein attaching the die comprises diffusion bonding the die to the chip carrier.

9. The method of claim 1, wherein attaching the die comprises thermocompression bonding the die to the chip carrier.

10. The method of claim 1, wherein attaching the die comprises reducing atmospheric pressure during attaching.

11. The method of claim 8, wherein the diffusion bonding comprises diffusion bonding at less than approximately 250° C.

12. The method of claim 1, wherein attaching the die comprises transient liquid phase bonding the die to the chip carrier.

13. The method of claim 1, wherein forming the metallization layer on the exterior surface of the die comprises electroplating the metallization layer.

14. The method of claim 1, wherein forming the metallization layer on the exterior surface of the die comprises electroless plating.

15. The method of claim 1, wherein forming the metallization layer on the exterior surface of the die comprises chemical vapor deposition (CVD).

16. The method of claim 1, wherein forming the metallization layer on the exterior surface of the die comprises physical vapor deposition (PVD).

17. A semiconductor device, comprising:
a chip carrier,
a die;
a gold-free bond layer attaching the die to the chip carrier, wherein the gold-free bond layer has a relatively uniform thickness of approximately 20 microns (μm) or less but more than 0.01 μm.

18. The semiconductor device of claim 17, wherein the gold-free bond layer comprises one of silver (Ag), copper (Cu), indium (In), bismuth (Bi), lead tin (PbSn), or tin silver (SnAg).

19. The semiconductor device of claim 17, wherein the gold-free bond layer comprises free solder.

20. The semiconductor device of claim 17, wherein the gold-free bond layer comprises an intermetallic compound (IMC) layer.
